(19) United States
(12) Patent Application Publication
(10) Pub. No.: US 2006/0153394 A1
(43) Pub. Date: Jul. 13, 2006

(54) Headset audio bypass apparatus and method

(76) Inventor: Nigel Beasley, Chesham (GB)

Correspondence Address: MORRISON & FOERSTER LLP, 12531 HIGH BLUFF DRIVE, SUITE 100, SAN DIEGO, CA, 92130-2040, US

(21) Appl. No.: 11/328,890

(22) Filed: Jan. 10, 2006

Related U.S. Application Data
(60) Provisional application No. 60/642,842, filed on Jan. 10, 2005.

(51) Int. Cl. H03G 3/20; H03G 9/00

(52) U.S. Cl. 381/57; 381/102

(57) ABSTRACT

An apparatus and method provides control over the relative level of audio and background sound for an audio device such as a headset or headphones. An input sound transducer can be provided and configured to convert ambient acoustical pressure into an electrical background signal representing the background sound. Noise cancellation circuitry create a cancellation signal that is the inverse of the electrical background signal. A summing component is coupled to the noise cancellation component and combines the cancellation signal with an audio signal representing audio program content and provides the combined electrical signal to an output sound transducer. A controller is coupled to the noise cancellation component and is configured to control the level of a cancellation signal relative to the audio signal, thereby controlling the mix of cancellation signal and audio signal reaching the output sound transducer.

This application claims priority to U.S. Patent Provisional Application Ser. No. 60/642,842, filed on Jan. 10, 2005, the disclosures of which are herein incorporated by reference in their entirety.

### BACKGROUND OF INVENTION

1. Field of the Invention

The present invention relates to audio headsets, and more particularly to an apparatus and method to facilitate enhanced usability thereof.

2. Description of Related Art

Our contemporary society enjoys numerous electronic devices that help to make our lives more productive, more comfortable and more efficient. One such device is the audio headset, which is a listening device that allows a user to hear audio material. Early examples of an audio headset included the monaural earpiece that was often seen accompanying the early transistor radio. Modern examples of an audio headset include stereo headphones used by casual listeners and audiophiles alike to enable a personal listening experience even in a public setting.

With the proliferation of portable audio and video players, the headset market has also exploded. People on the go or at home use an audio headset to allow them to listen to their electronic devices without external interruptions and without disturbing others. For example, on any given airline flight, one will see numerous passengers with his or her own audio or audio/video source such as, for example, a DVD player, MP3 player or the like. Headsets used with these and other devices allow the user to not only play the source material without disturbing others nearby, but also allow the user to at least partially screen out unwanted noises or audible distractions.

In fact, many contemporary headsets offer active or passive noise rejection or noise cancellation features to provide an enhanced listening experience. For example, passive systems may utilize a relatively tight seal around the perimeter of the ear or around the circumference of the ear canal to insulate the listener from unwanted noises. Active systems, on the other hand, may utilize electronic cancellation of undesirable background audio or noise.

Unfortunately, the advantages offered by many headsets also result in a disadvantage as well. That is, when listening to audio program content via a headset the user often experiences difficulty participating in a conversation with others around him or her or otherwise hearing certain background audible content that may be of interest. This is especially true with passive noise insulating or active noise cancellation devices, which make it particularly difficult for the user to hear a conversation, listen to someone speaking to them or otherwise hear outside audio information that may be of interest.

### SUMMARY OF THE INVENTION

In accordance with one embodiment, an apparatus to provide control over the relative level of audio and background sound includes: an input sound transducer configured to convert ambient acoustical pressure into an electrical background signal representing the background sound; noise cancellation circuitry coupled to the input sound transducer and configured to create a cancellation signal that is the inverse of the electrical background signal; a summing component coupled to the noise cancellation component and configured to combine the cancellation signal with an audio signal representing audio program content and for providing the combined electrical signal to an output sound transducer; and a controller coupled to the noise cancellation component and configured to control the level of a cancellation signal relative to the audio signal, thereby controlling the mix of cancellation signal and audio signal reaching the output sound transducer.

In accordance with another embodiment, an apparatus to provide control over the relative level of audio and background sound includes: an input sound transducer configured to convert ambient acoustical pressure into an background audio signal representing the background sound; an audio input line configured to accept an audio content signal representing audio program content; and audio bypass circuitry coupled to the input sound transducer and the audio input line and configured to adjust the level of electrical background signal relative to the audio signal. The audio bypass circuitry can be implemented, for example, using at least one of a switch, an amplifier, and a processor. A summer can also be included to combine the audio content signal with the background audio signal.

Additionally, cancellation circuitry can be provided to adjust the electrical background signal such that it provides a level of cancellation of the background sound when played through an output audio transducer. The cancellation circuitry can include at least one of an inverter, a compensation filter, and a digital signal processor.

In accordance with yet another embodiment, an audio headset can be provided that includes: an input sound transducer configured to convert ambient acoustical pressure into an background audio signal representing the background sound; an audio input line configured to accept an audio content signal representing audio program content; audio bypass circuitry coupled to the input sound transducer and the audio input line and configured to adjust the level of electrical background signal relative to the audio signal; a summer configured to combine the audio content signal with the background audio signal to create a combined output signal; and an output transducer configured to convert the combined output signal into an audible signal.

The audio headset can include cancellation circuitry to adjust the electrical background signal such that it provides a level of cancellation of the background sound when played through the output transducer.

In accordance with yet another embodiment, a method for controlling the level of audible program content relative to a background sound is provided. The method converts a background sound into a background audio signal representing the background sound; receives an audio content signal representing audio program content; adjusts the level of electrical background signal relative to the audio content signal; combines the audio content signal and the electrical background signal into a combined output signal; and provides the combined signal to a speaker or other audio driver.

### BRIEF DESCRIPTION OF THE DRAWINGS

The present invention, in accordance with one or more various embodiments, is described in detail with reference to the following figures. The drawings are provided for purposes of illustration only and merely depict typical or example embodiments of the invention. These drawings are provided to facilitate the reader's understanding of the invention and shall not be considered limiting of the breadth, scope, or applicability of the invention. It should be noted that for clarity and ease of illustration these drawings are not necessarily made to scale.

FIG. 1 is a diagram illustrating an example environment in which the invention can be implemented.

FIG. 2 is a diagram illustrating an example implementation for noise cancellation circuitry that can be implemented in accordance with one embodiment of the invention.

FIG. 3 is a diagram illustrating an example implementation of audio bypass circuitry in accordance with one embodiment of the invention.

FIG. 4 is a diagram illustrating an example operation of an audio bypass feature in accordance with one embodiment of the invention.

FIG. 5 is a diagram illustrating an example implementation of audio bypass circuitry in accordance with one embodiment of the invention.

FIG. 6 is a diagram illustrating an example implementation of audio bypass circuitry in accordance with one embodiment of the invention.

FIG. 7 is a diagram illustrating an example implementation of audio bypass in accordance with one embodiment of the invention.

FIG. 8 is a diagram illustrating an example implementation of audio bypass circuitry in accordance with one embodiment of the invention.

FIG. 9 is a diagram illustrating an example implementation of audio bypass in accordance with one embodiment of the invention.

FIG. 10 is a diagram illustrating an example implementation of audio bypass in accordance with one embodiment of the invention.

FIG. 11 is a diagram illustrating an example controller in accordance with one embodiment of the invention.

### DESCRIPTION OF THE PREFERRED EMBODIMENTS

The present invention is directed toward a system and method for providing an audio bypass feature for various headset applications that allow outside sounds or other background audio information to pass through the headset to the user's ears. In one embodiment, this audio bypass feature is enabled selectively by the user, but in other embodiments, user intervention is not utilized. The present invention is described herein in terms of an example application in a set of noise-canceling audio headphones. As will become apparent to one of ordinary skill in the art after reading this description, the present invention can be implemented in other headset applications where it may be useful or desirable for a user to allow outside audio information such as, for example, a conversation to pass through the headset so this information can be heard by the user.

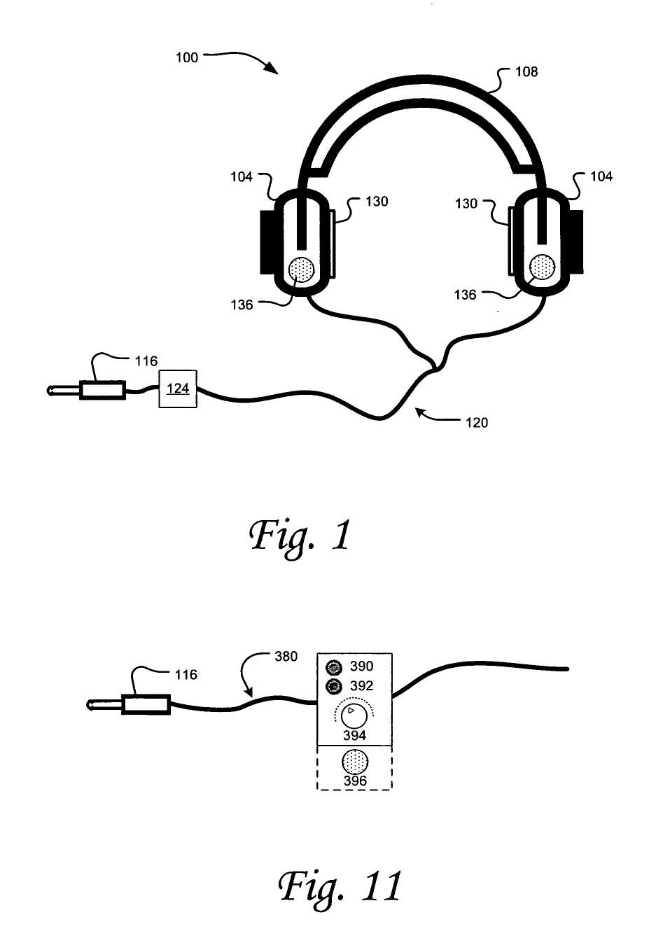

Thus, before describing the invention in detail, this example application of a noise-canceling audio headset is first described. FIG. 1 is a diagram illustrating one embodiment of a noise-canceling audio headset, which forms an example application for the present invention. Referring now to FIG. 1, this example noise-canceling audio headset 100 includes two ear pieces 104, a headband 108, an audio jack 116, audio cables 120, and optionally a switch or other control device 124. Typically contained within ear pieces 104 are speakers or other audio drivers, (not illustrated in FIG. 1) which can be used to translate electrical representations of an audio signal into an audible audio content that is capable of being heard by the human ear. Ear pieces 104 may also include insulating structure 130 (for example, padded rings around the perimeter) to provide more effective sound insulation, thus helping to better shield the user from background audio or other unwanted background noise originating outside the headset that may detract from the desired audio content being played through the audio headset 100.

Control device 124 may include controls such as, for example, a volume control, an on/off switch, a mute button, or other controls that allow the user to customize his or her listening experience. Control device 124 also provides a convenient location in which a battery, batteries, or other power source may be included to provide power to noise-cancellation headset 100. Alternatively one or more of these items can be included elsewhere in audio headset 100 including, for example, on or within ear pieces 104, headband 108 and so on.

In audio headsets 100 utilizing active noise-cancellation techniques, an input transducer 136, such as for example a microphone or other device, can be included in either or both earpieces 104 for transducing acoustic pressure outside of ear pieces 104 (e.g., audible background noise) to a corresponding audio signal, which is used by the noise-cancellation system to filter out or otherwise cancel the background noise.

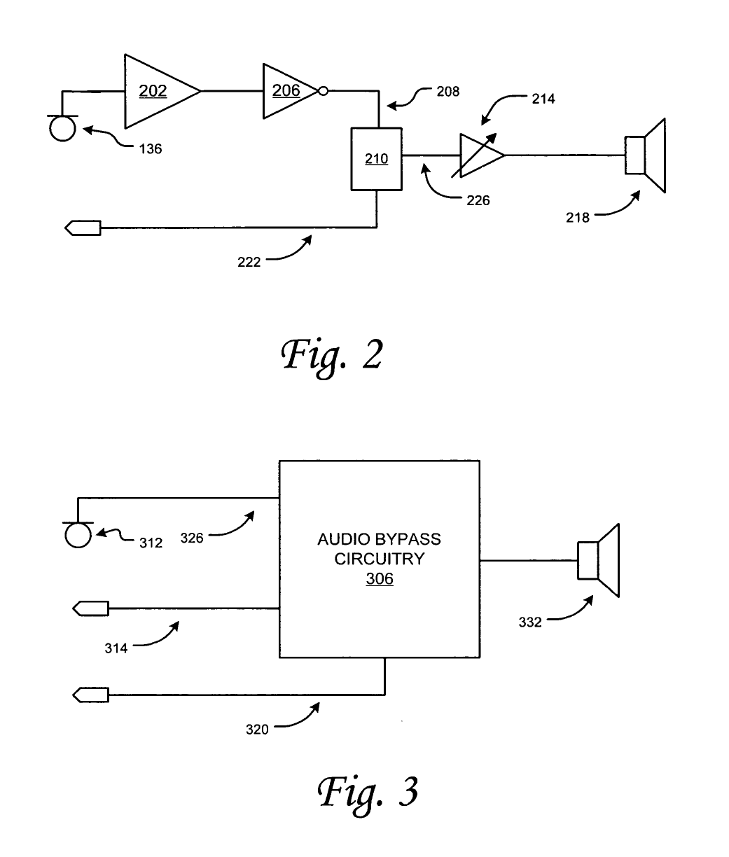

FIG. 2 is a simplified block diagram illustrating an example implementation for noise cancellation circuitry that can be included with noise-canceling headset 100. Referring now to FIG. 2, microphone 136 transduces the acoustical pressure generated by the unwanted background noise into an electrical signal that is enhanced by an amplifier such as pre-amp 202. The electrical signal is inverted by an inverter 206 to create an inverse of the original signal representing the background noise, thus creating a cancellation signal 208. Cancellation signal 208 can then be amplified via an amplifier 214, which is preferably a variable gain amplifier, and provided to drive a speaker 218 to cancel the external noise that may penetrate the ear piece 104. In the embodiment illustrated in FIG. 2, cancellation signal 208 is summed with the audio signal 222 via summer 210 to create a composite signal 226 to amplifier 214 to drive speaker 218 with an audio signal that includes the cancellation signal 208, thus canceling, at least partially, the unwanted noise.

Cancellation signal 208 can be generated using an inverter 206, a compensation filter, a DSP, or other circuitry, devices or techniques to create a signal that when provided to speaker 218 cancels all or part of the background noise transduced by microphone 136. The example application illustrated in FIG. 2 shows the use of an inverter 206. However, it will become apparent to one of ordinary skill in the art after reading this discussion how alternative techniques such as those provided in the foregoing examples can be implemented.

Having thus described an example environment in which the present invention can be applied, the present invention will now be described in greater detail in terms of this example environment. After reading this description, it will become apparent to one of ordinary skill in the art how to implement the invention in its various forms and embodiments in this or alternative environments in which it may be desirable to utilize the features and aspects of the present invention. FIG. 3 is a high-level block diagram illustrating an example implementation of the audio bypass feature according to one embodiment of the invention. Referring now to FIG. 3, the present invention includes audio bypass module 306, which is implemented to allow background sounds originating outside the headset to more readily be heard by the user of an audio headset. More particularly, in accordance with one embodiment of the invention, audio bypass module 306 can be implemented to allow a user to selectively engage or disengage the audio bypass feature to thereby allow selected background sounds to be heard by the user while the user is wearing an audio headset. In alternative embodiments, audio bypass module 306 can be implemented to automatically engage or disengage the audio bypass feature. Audio bypass module 306 in this and the other embodiments described herein can be implemented utilizing hardware, firmware, software, or a combination thereof, as may be desirable based on the given application.

An audio input is provided to accept the traditional audio signal 314 for the audio program content a user may desire to hear via a speaker 332, such as, for example, the audio stream from a CD player, MP3 player, radio, DVD player or other audio source. The audio input may be implemented using a jack, banana plug or any other wired connector, and could alternatively be implemented utilizing a wireless interface.

A control signal 320, typically generated by user interaction, can be utilized by audio bypass module 306 to allow an external audio signal transduced by a microphone 312 to pass through to speaker 332 such that that external audio signal 326 can be heard by the user without removing the audio headset. As discussed in the various embodiments presented herein, one or more control signals 320 can be generated by user interaction (e.g., via a control panel or other user interface) or generated automatically depending on the implementation.

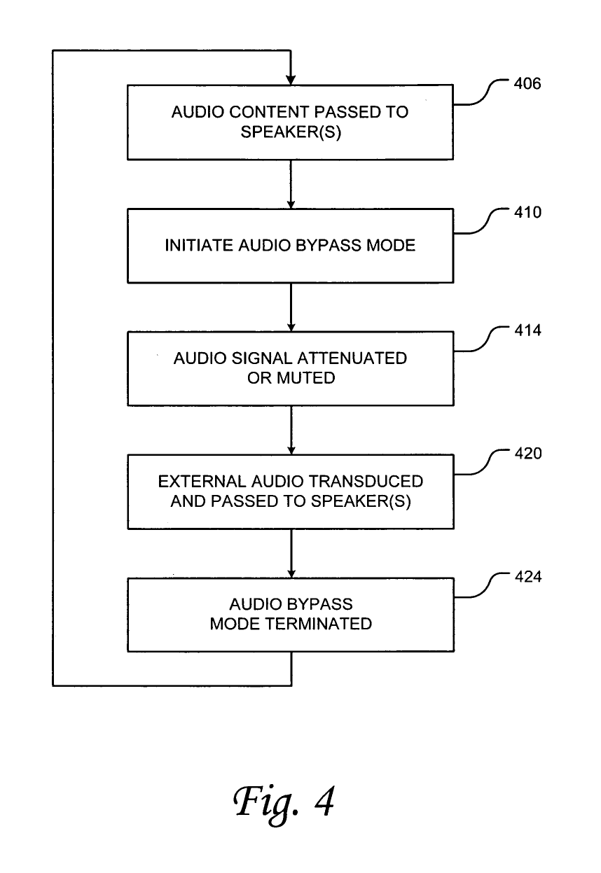

FIG. 4 is an operational flow diagram illustrating an example process for implementing audio bypass in accordance with one embodiment of the invention. Referring now to FIGS. 3 and 4, in a step 406, in conventional operation, audio content is passed to speaker 332 by audio bypass module 306. That is, for example, an audio signal 314 representing audio content from an electronic device can be heard via the ear pieces 104 in a user's noise-cancellation headset 100.

In a step 410, the audio bypass mode is initiated. In one embodiment, this can be accomplished by user interaction such as, for example, the user depressing a button or operating a switch to activate audio bypass module 306. In other embodiments, this may be accomplished, for example, by automated means such as, for example, voice or speech recognition, background audio level threshold detection or other techniques.

In a step 414, with audio bypass mode initiated, the audio signal 314 can be either attenuated or muted such that the audio program content is either softened before it reaches speaker 332 or is prevented from actually reaching speaker 332 so that it is diminished or not heard by the user during audio bypass mode.

In a step 420, the external audio transduced by a microphone 312 (which can be implemented as, for example, microphone 136 in the example environment) is passed to speaker 332, which converts the electrical signal into an audible signal that can be heard by the user via the headset speaker or speakers. In an environment of a noise cancellation headset 100, it may be desirable to diminish or inhibit the noise cancellation functionality so that the background audio can be better heard by the user.

In a step 424, when the audio bypass mode is terminated, audio signal 314 is returned to normal levels and the original audio content is once again passed to speaker 332 such that the user can resume listening to the audio content. Similar to initiating audio bypass mode, termination of the audio bypass mode can be accomplished by a manual means (e.g., via a button or switch etc.) or through automatic means (e.g., voice or speech recognition or audio level threshold detection and so on).

As will become apparent to one of ordinary skill in the art after reading this description, audio bypass module 306 can be implemented utilizing a number of different techniques. A few example embodiments for implementing audio bypass module 306 are now described. FIG. 5 is a diagram illustrating one example implementation of audio bypass module 306 in accordance with one embodiment of the invention. In the example illustrated in FIG. 5, audio signal 314 is a stereo signal and is thus provided as a left audio signal 314A and a right audio signal 314B. A microphone 312 transduces the acoustical pressure generated by the background noise (e.g., the background audio) thereby generating a background audio signal 526. In this example embodiment, audio bypass module 306 is illustrated as being implemented utilizing switches 522, 523, and 524. Switches 522, 523, and 524 can be implemented utilizing various technologies including, for example, FET switches or other switching techniques. Because various audio signals are being switched through switches 522, 523, and 524, it is desirable to utilize technologies that exhibit the appropriate frequency response characteristics for handling such audio signals. It is also often desirable that low cost means be used when implementing switches 522, 523, and 524. Additionally, it is important to consider isolation of the various signals in the device.

One or more control signals 520, as illustrated, are utilized to provide control information to configure switches 522, 523, and 524 to initiate and/or terminate the audio bypass mode. For example, to initiate the audio bypass mode, switches 522 and 524 would be set to the B position and switch 523 set to the A position. In this configuration, background audio signal 526 is passed through audio bypass module 306 and on to speakers 332A and 332B. Alternatively, when not in audio bypass mode, switches 522 and 524 are set to position A and switch 523 is set to position B, thus allowing audio signal 314A and audio signal 314B to pass to its respective speaker 332A and 332B.

Summers 532A and 532B can be used to combine the respective audio signals 314A and 314B with the background audio signal 526. Variable gain amplifiers 536A (or fixed gain amplifiers) can be utilized to provide amplification of the resultant signal prior to driving speakers 332A and 332B.

In the embodiment illustrated in FIG. 5, a single microphone 312 is illustrated as providing a background audio signal from a single source (i.e., microphone 312) to both speakers 332A, 332B in a stereo headset. As will become apparent to one of ordinary skill in the art after reading this description, a second microphone (not illustrated) and a second switch (not illustrated) can be provided in addition to microphone 312 and switch 523 to provide a separate background audio signal for each of the left and right channels.

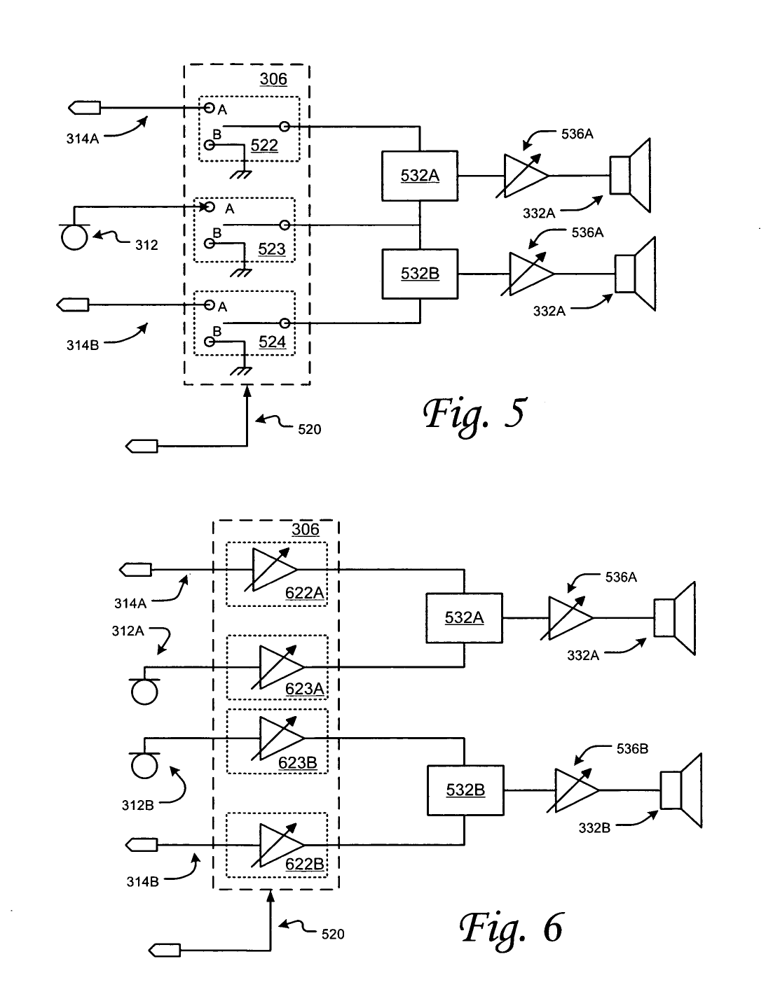

FIG. 6 is a simplified schematic diagram illustrating another example implementation of audio bypass module 306 in accordance with one embodiment of the invention. Referring now to FIG. 6, in the embodiment illustrated, switches 522, 523, and 524 have been replaced by amplifiers 622 and 623. More specifically, in the embodiment illustrated in FIG. 6, these amplifiers are illustrated as variable gain amplifiers. Note, however, that the embodiment illustrated in FIG. 6 includes two microphones 312A and 312B for left and right channel operation.

The operation of this embodiment is similar to the operation of FIG. 5, wherein one or more control signals 520 are utilized to provide input to audio bypass module 306 to selectively allow a background audio signal to pass through audio bypass module 306 to be heard by the user via speakers 332. Thus, when the audio bypass mode is initiated, control signal 520 can be utilized to cause audio signals 314A and 314B to be attenuated by variable gain amplifiers 622A and 622B, and background or outside audio signals 312A and 312B to be amplified by variable gain amplifiers 623A and 623B. Thus, in this embodiment, the signal level, and thus ultimate volume, of background audio signal 312 is increased relative to that of audio signal 314, thus enabling the user to better hear the background audio signal 312 over the audio program content 314 from the audio source of the electronic device. Also illustrated in the example provided in FIG. 6 are summers 532A, 532B and output amplifiers 536A, 536B. In the configuration illustrated in FIG. 6, two microphones 312A and 312B are provided such that a separate background audio signal can be provided for each channel of the headset. However, as would be apparent to one of ordinary skill in the art after reading this description, the embodiment can be implemented using a single microphone 312 and a single amplifier 623 to transduce and provide a single background audio signal to both channels of the listening device.

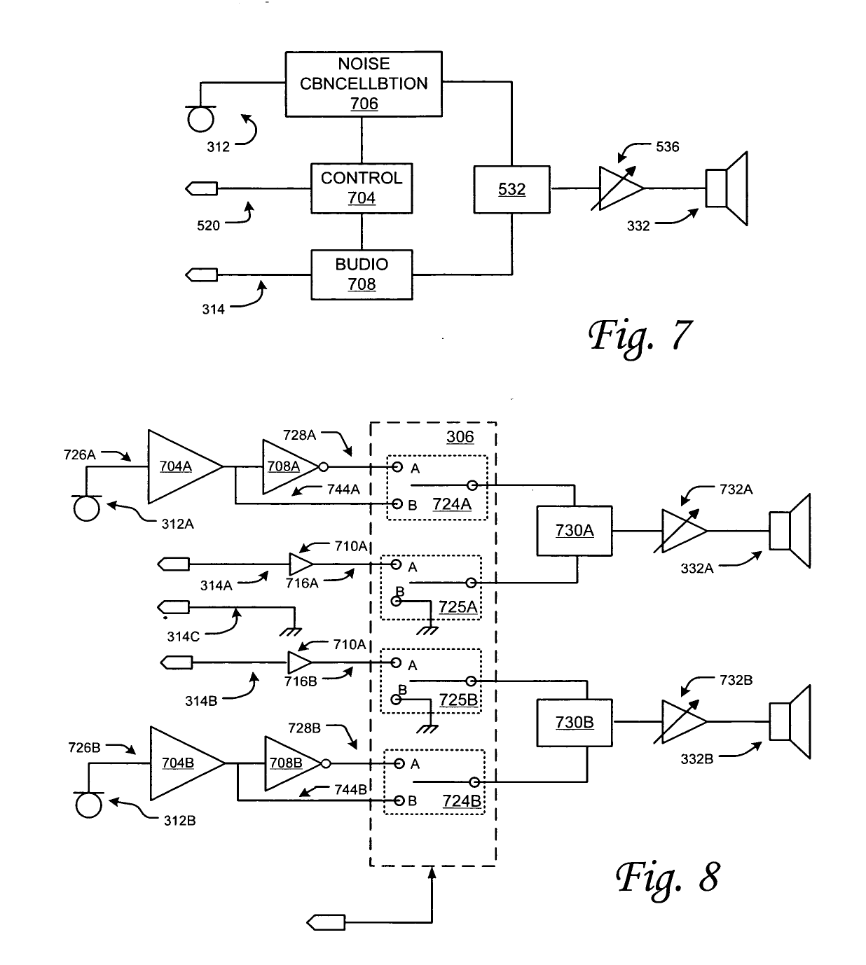

The embodiments described above with reference to FIGS. 5 and 6 illustrate example applications in which audio bypass module 306 is used in conjunction with headset devices having no noise-cancellation circuitry or utilizing passive noise attenuation techniques to filter out unwanted background noise from the listening environment. Now described are a plurality of embodiments that can be utilized in applications such as, for example, the example environment of a noise-cancellation headset 100 utilizing active noise-cancellation techniques. FIG. 7 is a simplified block diagram illustrating at a high level the implementation of an audio bypass mode with a noise-cancellation headset. Referring now to FIG. 7, the example implementation includes controller 704 that can be utilized to control a noise cancellation component 706 and an audio component 708 of the noise-canceling headset. In this example embodiment, when the audio bypass mode is initiated, controller 704 attenuates or mutes audio signal 314 and allows the background noise signal to pass through noise cancellation portion 706. This can be accomplished by bypassing or inhibiting the noise cancellation circuitry, allowing the external signal transduced by microphone 312 to be passed to speakers 332. Alternatively, this can also be accomplished by allowing noise cancellation portion 706 to continue unaltered or unadjusted. This is true especially, for example, in configurations where noise cancellation portion 706 is utilized to filter out only low frequency noises and does not affect, at least not to a great extent, noise in the frequency ranges of ordinary human speech. Also illustrated in the embodiment shown in FIG. 7 are a summer 532, amplifier 536 and speaker 332 to provide the selected audio content to the user. Although one audio channel is illustrated, it will become apparent to one of ordinary skill in the art how to implement the invention utilizing multiple channels.

FIG. 8 is a simplified schematic diagram illustrating an example implementation of the audio bypass feature in a noise-cancellation headset in accordance with one embodiment of the invention. Referring now to FIG. 8, the example implementation illustrated herein is that of a stereo or other dual-channel headset in which first and second audio signals 314A, 314B (e.g., left and right audio signals) are received and played via speakers 332. After reading this description, it will be apparent to one of ordinary skill in the art how to implement this embodiment in a monaural application or in applications having an alternative number of channels.

In normal operation, audio signals 314A and 314B are received from the audio source and can be conditioned utilizing buffer amps 710A and 710B, respectively. Audio signals 314A and 314B are typically received from the audio source via an audio jack such as, for example, an eighth inch stereo plug or other audio connecter. However, other input techniques, both hardwire and wireless, can be utilized. Conditioned audio signals 716A and 716B are switched by audio bypass module 306 to drivers 732A and 732B via mixers 730A and 730B such that they can be heard by the user on speakers 332A and 332B.

With the noise cancellation feature turned on, acoustical pressure generated by background noise is transduced by microphones 312A and 312B to create a background noise signals 726A and 726B that can be conditioned by optional driver/pre-amp 704A and 704B and ultimately inverted via inverters 708A and 708B to create noise-cancellation signals 728A and 728C. Noise-cancellation signals 728A and 728C are summed with conditioned audio signal 716A and 716B via summer 730 and amplified by driver 732 to provide an audio signal to the user that includes both the original audio program content and a component representative of the inverse of the background noise. Thus, when the background noise is combined with its inverse and this signal is used to drive speaker 332, the background noise is canceled such that it is not heard by the user (or it is at least diminished).

In the embodiment illustrated in FIG. 8, audio bypass module 306 comprises a plurality of switches similar to those utilized in the embodiment illustrated in FIG. 5. Thus, when the audio bypass mode is initiated, switches 724A and 724B are placed in the B position, as are switches 725A and 725B. Thus, in the audio bypass mode, the input audio signals 314A and 314B are muted and the inverters 708A and 708B utilized to create the cancellation signal are bypassed, thus allowing the background noise signals 726A and 726B to pass through to speakers 332A and 332B. In one example embodiment of this configuration, the gain of amplifiers 704 or amplifier 732 (or both) can be increased in the audio bypass mode to allow the background audio signal to be amplified to a greater extent so that it can be heard by the user. Thus, in this configuration, in the audio bypass mode, the background audio signal (for example, a conversation within earshot of the headset user) can be picked up by microphones 312A and 312B, amplified by the circuitry, and readily heard by the user via speakers 332A and 332B. When the audio bypass mode is terminated, switches 724A, 724B, 725A, and 725B can be returned to the A position such that background noise cancellation once again commences and the audio signals 314A, 314B can be passed through the respective componentry to speakers 332A, 332B. As discussed above, an inverter 708 can be implemented utilizing a number of different techniques to provide an inverse or complementary audio signal utilized to cancel out the background audio noise. This can be accomplished using inverters, compensation filters, and other known techniques.

Additionally, in this and other embodiments instead of an inverter 708, a band pass or other filter can be utilized to filter out unwanted background noise. For example, in the environment of an aircraft cabin, the unwanted background noise is often predominantly made up of low frequency components resulting from the roar of the aircraft engines. Thus, for applications utilized in such environments, it is possible to implement the noise-cancellation function a band pass filter to filter out low frequency sounds, thus allowing only higher frequency sounds to pass. Thus, in this embodiment, in addition to or in place of inverters 708, band pass filters can be utilized to limit audio at certain frequencies. Additionally, circuitry components or instrumentality can be utilized in signal paths 744A and 744B to enhance or amplify signals falling within the frequency range of normal human speech. Thus, for example, an amplifier and a band pass filter can be included where the transfer response of the band pass filter is tuned to allow frequency components within the range of human speech to be transferred to the speakers 332A, 332B for playback to the listener. Thus, in this embodiment, amplifying the range of frequencies covered by human speech can enhance the ability of the user to hear a conversation that is occurring outside the ear pieces and, thus, allow the user to participate in or listen to that conversation without necessarily removing the headphones.

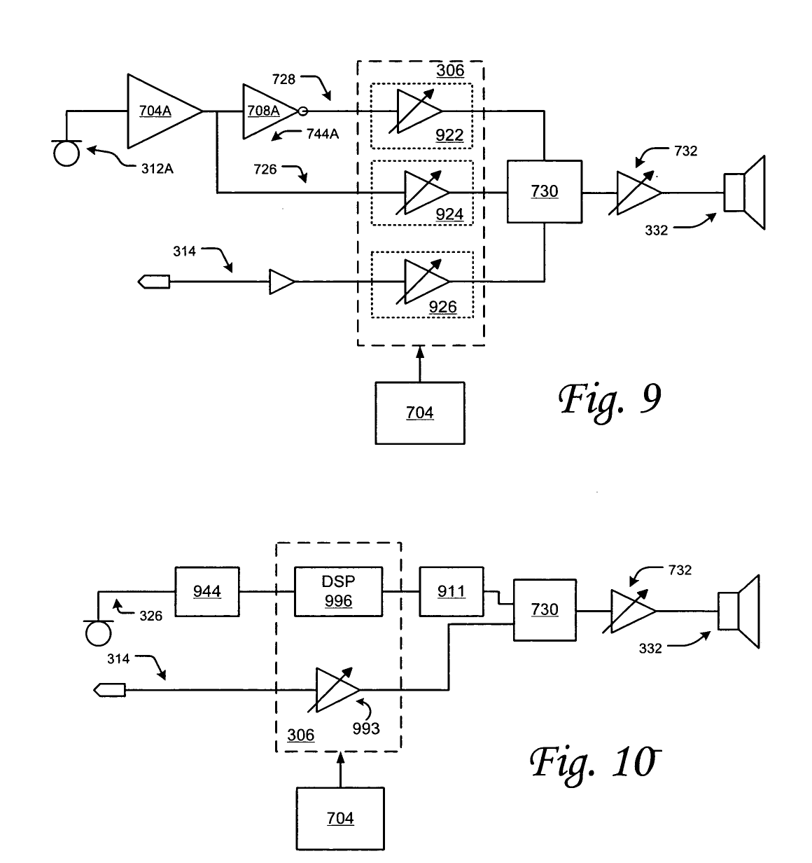

FIG. 9 is a simplified schematic diagram illustrating yet another application of the invention in the environment of a noise-canceling headset in accordance with one embodiment of the invention. FIG. 9 illustrates one audio channel; however, as described above, this embodiment can be implemented in applications utilizing a plurality of audio channels including, for example, a stereo headset. Referring now to FIG. 9, bypass module 306 is implemented using a plurality of amplifiers, which in the illustrated embodiment are variable gain amplifiers 922, 924, and 926. Variable gain amplifiers 922, 924, and 926 can be implemented in place of switches 724 and 725 illustrated in FIG. 8. More particularly, in this embodiment, controller 704 can be utilized to control the gain of amplifiers 922, 924, and 926 to selectively pass cancellation signal 728, background audio signal 726, or the audio signal 314. Preferably, when the audio bypass mode is initiated, the gain of variable gain amplifiers 922 and 926 is attenuated such that noise cancellation signal 728 and audio signal 314 are attenuated and the gain of variable gain amplifier 924 is increased such that the background audio signal 726 is amplified and readily heard by the user through speaker 332. Conversely, when the bypass mode is terminated, the gain of variable gain amplifier 924 is turned down such that the background audio signal 726 is no longer amplified (or is attenuated to some extent). Additionally, the gain of variable gain amplifier 926 is increased such that audio signal 314 is amplified and can be readily heard by the user via speaker 332. Also, the gain on variable gain amplifier 922 can be increased such that noise cancellation signal 728 is amplified and can be utilized in conjunction with audio signal 314 to minimize the amount of background noise heard by the user.

In yet another alternative embodiment, audio bypass module 306 can be implemented utilizing DSP technology. For example, in this embodiment, one or more analog/digital converters (ADC) can be utilized to digitize either or both of background noise signal 326 and audio signal 314. Once digitized, these signals can be processed utilizing a digital signal processor to, for example, amplify the speech signal, diminish the background noise, and inhibit the audio signal 314 from passing through to speaker 332. One example implementation utilizing DSP technology is illustrated in FIG. 10 in accordance with one embodiment of the invention. Referring now to FIG. 10, A/D converter 944 is utilized to digitize background noise signal 326. A digital signal processor 996 can be utilized to provide the noise-cancellation functions desired to diminish or eliminate undesirable background noise from the content heard by the user. D/A converter 911 is used to perform a digital to analog conversion such that the resultant noise cancellation signal can be converted to an audible signal via speaker 332. Additionally, a variable gain amplifier (or, alternatively, a switch or other component or instrumentality) 993 can be included to attenuate or amplify audio signal 314. Thus, when the audio bypass mode is initiated, the gain of variable gain amplifier 993 can be decreased to minimize the level of audio signal 314 while the operation of DSP 996 occurs such that the noise cancellation features are inhibited and the background audio signal 314 is allowed to pass through to speaker 332. More particularly, in one embodiment, the DSP 996 can be utilized to actually enhance the background audio signal such that the conversation or other audio that the user desires to hear in the bypass mode is better heard via speaker 332.

The above description provides details on a plurality of embodiments that utilize some form of audio bypass module 306 that optionally attenuates an audio signal 314 such that a background signal 326 can be heard by the user via speaker 332. In the illustrated embodiments, a microphone 312 (or 136 in the example application) is included to detect and transduce the acoustical pressure generated by the background noise that the user wishes to hear. In the example environment illustrated in FIG. 1, microphone 136 is provided in ear piece 104. In fact, in the embodiment illustrated in FIG. 1, there are two microphones 136, one in each ear piece 104. This is often the configuration found with noise-cancellation headsets 100 with which the invention can be implemented. Alternatively, microphones 312 can be implemented internal to ear piece 104 as opposed to externally, as illustrated in FIG. 1. In this embodiment, it may be more difficult to detect background sounds that are external to the ear pieces, as the ear pieces 104 may provide insulative properties shielding an internal microphone from such conversations. However, in such an environment, various combinations of filtering and amplification as discussed above may be utilized to further enhance the audibility of background audio picked up by internal microphones. Although not illustrated, in yet another embodiment, one or more microphones can be provided in other locations such as, for example, on or in proximity to headband 108, somewhere along cord 120, or integrated with control device 124. Although not required, it is anticipated that in noise cancellation applications, microphones 136 will be positioned somewhere in the proximity of ear pieces 104 such that, when they are performing the noise-cancellation function, they do a better job of approximating the sound that is to be canceled from the ultimate signal.

Although some of the above embodiments discuss utilizing as microphones 312 existing microphones 136 that are also utilized for noise cancellation, it is also possible to implement the invention utilizing one or more additional microphones 312 rather than utilizing the existing microphones 136 provided for noise-cancellation purposes. For example, it may be desirable to provide one or more microphones 312 on or near control device 124, headband 108, cord 120 or jack 116. One advantage, depending on the alternative placement, is that it may allow the microphone(s) 312 to be directed toward the source of the background audio for better pickup.

A user interface device can be included to allow the user to control one or more features of the audio bypass function. FIG. 11 is a diagram illustrating an example implementation of such a control device in accordance with one embodiment of the invention. Referring now to FIG. 11, illustrated is a control device 372 that is utilized to provide manual control of one or more of the features of the invention. The control device 372 illustrated in FIG. 11 is illustrated as being positioned along audio cables 380; however, other locations are possible, including on either or both ear pieces 104 or on headband 108 or in conjunction with jack 116. In one embodiment, control device 372 is hardwired in with the headset; however, wireless control devices 372 are also contemplated.

The features included with control device 372 in the illustrated example can include a mute button 390, an audio bypass button 392, a volume control 394, and a speaker 396, although each of these need not be present with a control device 372 and alternatives are possible, depending on the desired implementation. Mute button 390 can be utilized to mute the audio signal sent to the headset, thereby silencing in its entirety the audio content provided by the speakers. Alternatively, or in addition, a mute button can be provided that mutes only the original audio program content such that background audio can be heard without having to be heard above the audio signal (or vice versa). An audio bypass button 392 can be provided to allow the user to manually enter the audio bypass mode. Thus, depressing this button (or flicking the switch, etc.) allows the user to manually enter the audio bypass mode and utilize the features discussed above.

Volume control 394 can be included and utilized to adjust the audio volume presented by the headset. In one embodiment, this can adjust the volume for all features; however, one or more volume knobs 394 can be included to adjust individually if desired the audio content playback level, the background audio level, the noise cancellation level, and so forth.

As discussed above, a microphone 396 can also be included on the control device which can be used in addition to or as an alternative to other microphones that may be positioned elsewhere such as, for example, on ear pieces 104. Although jack 116 in this embodiment is illustrated as a standard stereo plug, it is contemplated that other connection devices can be utilized to receive the audio playback signal such as, for example, USB connectors, wireless communication ports, and so on.

In addition to utilizing a manual control to enter or exit the audio bypass mode, an automatic mode can be included wherein the audio bypass mode is controlled automatically based on the occurrence of one or more events. For example, in one embodiment, voice or speech recognition techniques can be utilized to allow the headset to enter the audio bypass mode in response to a command that is spoken by the user. Thus, for example, the user can program the device to enter the audio bypass mode when a particular word or phrase is spoken. For example, the headset in this embodiment could be programmed to respond to a phrase such as “Could you repeat that?” Thereby enabling the audio bypass mode when the user asks another person to repeat what they have just said. As another example, the device may be programmed to enter automatically the audio bypass mode when a background audio level is sensed that is louder or at a higher level than the ambient background noise or, for example, when a particular threshold is reached. Thus, for example, in this application, when the device senses that the user has spoken (as words spoken by the user may be sensed by the device at a level louder than the background noise), the device could automatically enter the audio bypass mode.

Additionally, timeout features can be provided to allow the device to automatically terminate the audio bypass mode upon the passage of a specified amount of time. This could be preprogrammed or user selected and controlled, depending on the implementation.

Various embodiments of the invention and implementation examples have been described above. However, it is understood that these various embodiments and examples are exemplary only and should not serve to limit the scope of the invention. It is also readily understood by those of ordinary skill in the art how to design and implement the disclosed embodiments using alternative architectures, processes, functionality, structures, and implementations. In sum, after reading this description, various modifications of and alternatives to the preferred embodiments described above can be implemented by those of ordinary skill in the art, without undue experimentation. These various modifications and alternatives are contemplated to be within the spirit and scope of the invention.

As an example of such modifications and alternatives and without limiting the generality of the foregoing, the example embodiments described herein illustrate a configuration utilizing a particular configuration of amplifiers and summers for combining and driving the various signals. As will be apparent to one of ordinary skill in the art after reading this disclosure, amplifiers could be provided elsewhere in the chain and summers can be provided as summing amplifiers. Also as would be apparent to one of ordinary skill in the art after reading this description, the circuitry can also include appropriate drivers, pre-amps, buffer amps, or other components or instrumentalities, as desired or appropriate to further condition the various audio signals. Furthermore, the schematic diagrams are provided to illustrate example implementations of various embodiments of the functionality of the audio bypass feature, and one of ordinary skill in the art after reading this description will understand how to implement these features and functions utilizing alternative configurations of hardware, software, firmware or combinations thereof. Likewise, particular implementations of switching functionality are disclosed herein in terms of FET switches and variable gain amplifiers. It would be apparent to one of ordinary skill in the art after reading this description how to implement the functionality of selecting and deselecting, or amplifying and attenuating selected audio signals to achieve the desired effects.

Terms and phrases used in this document, and variations thereof, unless otherwise expressly stated, should be construed as open ended as opposed to limiting. As examples of the foregoing: the term “including” should be read as mean “including, without limitation” or the like; the term “example” is used to provide exemplary instances of the item in discussion, not an exhaustive or limiting list thereof; and adjectives like “conventional,” “traditional,” “normal,” “standard,” and terms of similar meaning should not be construed as limiting the item described to a given time period or to an item available as of a given time, but instead should be read to encompass conventional, traditional, normal, or standard technologies that may be available now or at any time in the future. Likewise, a group of items linked with the conjunction “and” should not be read as requiring that each and every one of those items be present in the grouping, but rather should be read as “and/or” unless expressly stated otherwise.

What is claimed is:

1. An apparatus to provide control over the relative level of audio and background sound, comprising:
an input sound transducer configured to convert ambient acoustical pressure into an electrical background signal representing the background sound;
noise cancellation circuitry coupled to the input sound transducer and configured to create a cancellation signal that is the inverse of the electrical background signal;
a summer coupled to the noise cancellation circuitry and configured to combine the cancellation signal with an audio signal representing audio program content and for providing the combined electrical signal to an output sound transducer; and
a controller coupled to the noise cancellation circuitry and configured to control the level of a cancellation signal relative to the audio signal, thereby controlling the mix of cancellation signal and audio signal reaching the output sound transducer.

2. The apparatus of claim 1, wherein the cancellation circuitry comprises at least one of an inverter, a compensation filter, and a digital signal processor.

3. The apparatus of claim 1, wherein the controller is configured to attenuate or mute the audio signal.

4. The apparatus of claim 1, wherein the controller is configured to attenuate or mute the cancellation signal.

5. The apparatus of claim 1, wherein the controller is configured to inhibit or diminish functionality of the noise cancellation circuitry.

6. The apparatus of claim 1, wherein the controller is configured to cause the electrical background signal to bypass the noise cancellation circuitry.

7. An apparatus to provide control over the relative level of audio and background sound, comprising:
an input sound transducer configured to convert ambient acoustical pressure into an background audio signal representing the background sound;
an audio input line configured to accept an audio content signal representing audio program content; and
audio bypass circuitry coupled to the input sound transducer and the audio input line and configured to adjust the level of electrical background signal relative to the audio signal.

8. The apparatus of claim 7, wherein the audio bypass circuitry comprises at least one of a switch, an amplifier, and a processor.

9. The apparatus of claim 7, further comprising a summer configured to combine the audio content signal with the background audio signal.

10. The apparatus of claim 7, further comprising cancellation circuitry coupled to the input sound transducer and configured to adjust the electrical background signal such that it provides a level of cancellation of the background sound when played through an output audio transducer.

11. The apparatus of claim 10, wherein the cancellation circuitry comprises at least one of an inverter, a compensation filter, and a digital signal processor.

12. The apparatus of claim 10, wherein the audio bypass circuitry is configured to cause the electrical background signal to bypass the noise cancellation circuitry.

13. The apparatus of claim 7, wherein the audio bypass circuitry is configured to attenuate or mute the audio signal.

14. The apparatus of claim 7, wherein the audio bypass circuitry is configured to attenuate or mute the cancellation signal.

15. The apparatus of claim 7, wherein the audio bypass circuitry is configured to inhibit or diminish functionality of the noise cancellation circuitry.

16. The apparatus of claim 7, wherein engagement of the audio bypass circuitry is controlled by at least one of voice recognition, speech recognition, and background audio level threshold detection.

17. The apparatus of claim 7, further comprising a user interface device configured to allow a user to control the audio bypass circuitry.

18. The apparatus of claim 7, further comprising means for automatically engaging the audio bypass circuitry.

19. The apparatus of claim 18, wherein the means for automatically engaging comprises voice recognition, speech recognition, and background audio level threshold detection.

20. An audio headset, comprising:
an input sound transducer configured to convert ambient acoustical pressure into an background audio signal representing the background sound;
an audio input line configured to accept an audio content signal representing audio program content;
audio bypass circuitry coupled to the input sound transducer and the audio input line and configured to adjust the level of electrical background signal relative to the audio signal;
a summer configured to combine the audio content signal with the background audio signal to create a combined output signal; and
an output transducer configured to convert the combined output signal into an audible signal.

21. The audio headset of claim 20, wherein the audio bypass circuitry comprises at least one of a switch, an amplifier, and a processor.

22. The audio headset of claim 20, further comprising cancellation circuitry coupled to the input sound transducer and configured to adjust the electrical background signal such that it provides a level of cancellation of the background sound when played through the output transducer.

23. The audio headset of claim 22, wherein the cancellation circuitry comprises at least one of an inverter, a compensation filter, and a digital signal processor.

24. The audio headset of claim 20, wherein the audio bypass circuitry is configured to cause the electrical background signal to bypass the noise cancellation circuitry.

25. The audio headset of claim 20, wherein the audio bypass circuitry is configured to attenuate or mute the audio signal.

26. The audio headset of claim 20, wherein the audio bypass circuitry is configured to attenuate or mute the cancellation signal.

27. The audio headset of claim 20, wherein the audio bypass circuitry is configured to inhibit or diminish functionality of the noise cancellation circuitry.

28. The audio headset of claim 20, wherein engagement of the audio bypass circuitry is controlled by at least one of voice recognition, speech recognition, and background audio level threshold detection.

29. The audio headset of claim 20, further comprising a user interface device configured to allow a user to control the audio bypass circuitry.

30. The audio headset of claim 20, further comprising means for automatically engaging the audio bypass circuitry.

31. The audio headset of claim 30, wherein the means for automatically engaging comprises voice recognition, speech recognition, and background audio level threshold detection.

32. A method for controlling the level of audible program content relative to a background sound, the method comprising the steps of:
converting a background sound into a background audio signal representing the background sound;
receiving an audio content signal representing audio program content;
adjusting the level of electrical background signal relative to the audio content signal;
combining the audio content signal and the electrical background signal into a combined output signal; and
providing the combined signal to a speaker or other audio driver.

33. The method of claim 32, wherein the step of adjusting causes the electrical background signal to bypass the noise cancellation circuitry.

34. The method of claim 32, wherein the step of adjusting attenuates or mutes the audio signal.

35. The method of claim 32, wherein the step of adjusting attenuates or mutes the cancellation signal.

36. The method of claim 32, wherein the step of adjusting inhibits or diminishes functionality of the noise cancellation circuitry.

37. The method of claim 32, wherein the step of adjusting is controlled by at least one of voice recognition, speech recognition, and background audio level threshold detection.

38. The method of claim 32, wherein the step of adjusting is controlled by a user.

39. An apparatus for controlling a relative level of audio and background sound in an audio playback device, comprising:
means for converting ambient acoustical pressure into an electrical background signal representing background sound;
means for controlling the signal level of an electrical background signal relative to the level of an electrical audio signal representing audio program content;
means for receiving an electrical audio signal representing audio program content;
means for combining an electrical background signal with an electrical audio signal and The method of claim 32, wherein the step of adjusting is controlled by providing the combined electrical background and audio signal to an output sound transducer.
